(19) United States
(12) Patent Application Publication
(10) Pub. No.: US 2025/0142980 A1
(43) Pub. Date: May 1, 2025

(54) LAYER CONTAINING EFFECT PIGMENTS AND SCATTERING ADDITIVES

(71) Applicant: Merck Patent GmbH, Darmstadt (DE)

(72) Inventors: Sebastian BARTH, DARMSTADT (DE); Laurent DELOUX, DARMSTADT (DE); Marc HUNGER, DARMSTADT (DE); Zhen WENG, SHANGHAI (CN); Claudio BRIGHINA, DARMSTADT (DE); Jan-Niclas KONZ, SCHWALBACH (DE)

(73) Assignee: Merck Patent GmbH, Darmstadt (DE)

(21) Appl. No.: 18/682,850

(22) PCT Filed: Aug. 9, 2022
(86) PCT No.: PCT/EP2022/072291

§ 371 Date: Feb. 9, 2024

(30) Foreign Application Priority Data
Aug. 12, 2021 (EP) 21190949.4
Sep. 17, 2021 (CN) 202111090721.2

(51) Int. Cl. H10F 19/80; B29C 48/00; B29K 105/00; B29L 31/34; C08K 3/30; C08K 7/16; C08K 7/28; H10F 19/90; H10F 77/00; H10F 77/42; H10K 39/18

(52) U.S. Cl. CPC H10F 19/804; B29C 48/023; C08K 3/30; C08K 7/16; C08K 7/28; H10F 19/902; H10F 77/42; H10F 77/937; B29K 2023/06; B29K 2105/0032; B29K 2105/0067; B29K 2995/002; B29K 2995/0026; B29L 2031/3412; C08K 2003/3045; C08K 2201/005; H10K 39/18

(57) ABSTRACT

A layer, sheet or film containing one or more flake-form effect pigments and one or more light scattering centers, methods for its preparation, its use for any type of device collecting solar cell energy, including but not limited to coloring solar cells or solar cell modules, and devices collecting solar cell energy, including but not limited to colored solar cells or colored solar cell modules, comprising such a layer, sheet or film, and methods for their preparation.

### CROSS-REFERENCE TO RELATED APPLICATIONS

This application is a U.S. national stage application claiming priority under 35 U.S.C. §§ 120 and 365 (c) of and to PCT International Application No. PCT/EP2022/072291, filed Aug. 9, 2022, which claims priority under 35 U.S.C. §§ 119 (a) and 365 (b) of and to European Application No. 2119049.4, filed Aug. 12, 2021, and Chinese Application No. 202111090721.2, filed Sep. 17, 2021, each of which are incorporated herein in their entirety and for all purposes.

### BACKGROUND

The invention relates to a layer, sheet or film containing one or more flake-form effect pigments and one or more light scattering centers, to methods for its preparation, to its use for any type of device collecting solar cell energy, including but not limited to coloring solar cells or solar cell modules, and to devices collecting solar cell energy, including but not limited to colored solar cells or colored solar cell modules, comprising such a layer, sheet or film and to methods for their preparation.

Solar cells have shown a great success over the last years and have surpassed the global grid-connected installation of 600 GW in 2019 with the majority being installed in utility scale. The basic function of all solar cells relies upon a photoactive material that absorbs light and generates an excited electron-hole pair. This electron-hole pair is separated within the solar cell by areas with different mobilities for electrons and holes, so called p-n junctions. As different kinds of light absorbing materials can be used, in the solar industry different kinds of solar cell technologies are known:
1) Crystalline silicon solar cells (mono crystalline c-Si and multi crystalline mc-Si)
2) Cadmium-Telluride Solar cells (CdTe)
3) Copper-Indium-Gallium-Diselenide (CIGS/CIS)
4) Amorphous silicon solar cells (a-Si)
5) III/V solar cells like Gallium-Arsenide (GaAs) solar cells or multi-junction solar cells consisting of stacks of group III and group V elements like Germanium/Indium-(Aluminium)-Gallium-Arsenide or phosphide (In(Al)GaAs/P)
6) Dye sensitized solar cells (DSSC)
7) Organic solar cells (OSC)
8) Perovskite solar cells (PSC)
9) Quantum dot solar cells (QSC)
10) Other II/VI solar cells consisting of elements of group II and group VI like Zinkselenide (ZnSe) or Ironsulfide (FeS)
11) Tandem solar cells

Nevertheless, using more surfaces e.g. of buildings and other surfaces on objects (e.g. cars) would increase the overall surface area which could be used for solar energy production. For this purpose, new techniques and approaches to make solar cells with appealing colors and color shades and to increase efficiencies under different angles of incidence are of major interest for the solar energy business.

WO 2019/122079A1 discloses a method of coloring state of the art single solar cells, or solar cell modules made of a plurality of electrically interconnected solar cells, by incorporating effect pigments into an application medium, like for example glass color or a transparent lamination material or an encapsulant, which is then subsequently applied to the front side of the solar cell. The effect pigments are semi-transparent and control the color of the light-incident surface without imparting the solar cell efficiency.

However, it has been observed that, due to the translucent coloring provided by the pigment containing layer at the light-incident surface, the solar cell structure and/or its conducting parts may still be visible at least partially through the protective glass and encapsulant film. Such an appearance of undesired patterns is a drawback which can limit the use of colored solar cells especially in areas like facades of buildings or other areas of building integrated photovoltaics. Also, it has been observed that the intensity of the color is dependent on the viewing angle, which may render the color effect less appealing for certain uses.

WO 2019/122079A1 proposes using a homogeneous dark colored background to enhance uniformity of the appearance, and/or blackening the conducting parts of the solar cell module to suppress the appearance of undesired patterns. However, this requires additional process steps or components and increases the time and costs of the solar module production process.

U.S. Pat. No. 5,807,440 describes a colored photovoltaic device comprising at its light incident side a coloring layer containing colorants, pigments or dyes, and further comprising a diffuser layer which provides a haze characteristic of 15 to 90%. The diffuser layer may comprise a white or near-colorless pigment, a porous resin or an insoluble resin dispersed in a translucent resin. However, the examples of this document report that a photovoltaic device comprising a coloring layer with an absorbing dye and an additional diffuser layer shows a loss in short-circuit current of 32 to 36% compared to a reference device without the diffuser layer. Moreover, the use of a separate diffuser layer in addition to the coloring layer makes the solar module production process more complicated and increases process time and costs.

### SUMMARY

It is therefore an object of the present invention to provide improved coloring layers for solar cells and solar cell modules, which do not have the drawbacks observed in prior art films and show good color reflection intensity on broad range viewing angle, while avoiding undesired visible patterns e.g. of strings or bus bars. Another object of the present invention is to provide improved colored solar cells and colored solar cell modules comprising such coloring layers and a more time- and cost-effective process for their production.

It was surprisingly found that one or more of these objects could be achieved by providing a layer, sheet or film as disclosed and claimed hereinafter, which comprises one or more effect pigments and further comprises one or more light scattering centers, like for example scattering particles, and as a result does not appear transparent but shows a certain haze, while still providing the desired color effect against a dark background. It was surprisingly found that, by adding such a layer at the front side of a solar cell module, it is possible to reduce the appearance of undesired dark patterns of the cells and strings/bus bars in the colored solar cell or solar cell module and to decrease dependency of color intensity on viewing angle, while still maintaining a high transmission of the pigment-containing layer and thus contributing to a high solar cell efficiency.

It has also been surprisingly found that the light scattering centers render the colored layer more opaque and hide unequal colors, giving a more uniform color to the whole solar panel. At the same time the efficiency of the solar cells is not significantly reduced by the light scattering centers and can even be increased, as demonstrated in the examples below.

The present application thus relates to a layer, sheet or film comprising one or more effect pigments consisting of a transparent or semi-transparent flake-form substrate coated with one or more layers of transparent or semi-transparent materials and optionally a post coating, and further comprising one or more light scattering centers.

The application further relates to a process of preparing a layer, sheet or film as described above and below.

The application further relates to the use of a layer, sheet or film as described above and below as coloring layer, in particular as coloring encapsulant layer or glass color, of a solar cell module.

The application further relates to a colored solar cell or colored solar cell module comprising a layer, sheet or film as described above and below.

The application further relates to a colored solar cell or colored solar cell module comprising the following components:
a transparent front cover layer (hereinafter also briefly referred to as “front sheet”),
optionally a further transparent layer at the front side of the solar cell,
one or more solar cells, or an array of solar cells which are electrically interconnected by conducting parts, preferably by bus bars,
a rear sheet,
wherein the transparent front cover layer, or the further transparent layer at the front side of the solar cell, comprises one or more effect pigments consisting of a transparent or semi-transparent flake-form substrate coated with one or more layers of transparent or semi-transparent materials and optionally a post coating, and further comprises one or more light scattering centers.

The application further relates to a process of preparing a colored solar cell or colored solar cell module as described above and below.

### BRIEF DESCRIPTION OF THE DRAWING FIGURES

The above-mentioned and other features and advantages of this invention, and the manner of attaining them, will become more apparent, and the invention will be better understood, by reference to the following description of an embodiment of the invention taken in conjunction with the accompanying drawings, wherein:

FIG. 1 is schematic illustration of a solar cell module according to an embodiment of the present invention;

FIG. 2 and FIG. 3 each depict transmission and haze values for certain inventive and comparative films prepared and tested as described in Example 1;

FIG. 4 shows optical images of inventive and comparative films as prepared in Example 2;

FIG. 5 depicts transmission and haze values for glass plates with layers according to the invention and for glass plates with a reference layer as described in Example 3.

FIG. 6 depicts transmission values for the coated samples as described in Example 4; and

FIG. 7 depicts the light loss rate for the coated samples obtained by integrating the transmission curves of FIG. 6.

### DETAILED DESCRIPTION

Above and below, the term “light scattering center” is understood to include various kinds of scattering centers, including but not limited to scattering particles or other additives, bubbles, droplets, density fluctuations in fluids, crystallites in polycrystalline solids, defects in monocrystalline solids, surface roughness spots etc. The scattering effect caused by the scattering centers in accordance with the present invention can also be understood as diffuse reflection, in contrast to specular reflection, and, unless stated otherwise, means scattering of light in the visible, UV and IR range, preferably in the range from 200 to 1200 nm, more preferably in the range from 300 to 1000 nm.

Above and below, the term “front side” of the solar cell or solar cell module means the light-receiving side or the side facing incident light, and the term “rear side” or “back side” of the solar cell or solar cell module means the side opposite to the radiation-receiving side or facing away from incident light. The terms “front glass/sheet” or “front encapsulant film” mean the glass, sheet or encapsulant film provided on the front side of the solar cell or solar cell module, and the terms “rear glass/sheet” and “rear encapsulant film” mean the glass, sheet or encapsulant film provided on the rear side of the solar cell or solar cell module.

Above and below, unless stated otherwise the term “solar cell” is understood to encompass both single solar cells and solar cell modules, as well as arrays, strings or patterns of the aforementioned. Likewise the term “solar cell modules” is understood to encompass also single solar cells unless stated otherwise.

Above and below, unless stated otherwise weight percentages of the light scattering particles and effect pigments are based on the total weight of the solid part of the layer, sheet or film.

Above and below, the term “medium particle size D50” means the particle size in microns that splits the size distribution such that 50% of the particles have a size below and 50% of the particles have a size above this value (also known as median diameter). Unless stated otherwise, the values of the medium particle size D50 are obtained with a Malvern MS2000 equipment.

Hereinafter, the layer, sheet or film according to the invention is also briefly referred to as “layer”, which is understood to be inclusive of a layer, sheet or film according to the invention as described above or below.

The present invention offers a highly efficient method of coloring state of the art solar cells, as well as solar cell modules made of a plurality of electrically interconnected solar cells, with great flexibility and achieving a huge range of different colors with a low or negligible loss in solar cell efficiency, and a high level of long term stability. Additionally, the invention provides a solution to achieve a high color uniformity and good color intensity on every viewing angle where the bus bars and the individual solar cells are less visible and at the same time a low or negligible loss of solar cell efficiency is achieved.

Thus, it was surprisingly found that, by adding a light scattering additive to the layer containing the effect pigments at the front side of the solar cell, it is possible to reduce or even avoid the appearance of undesired dark patterns of the cells and strings/bus bars in the colored solar cell or solar cell module and to decrease dependency of color intensity on viewing angle, while maintaining high transparency of the pigment-containing layer and thus ensuring a high quantum efficiency of the solar cell.

In particular, it was surprisingly found that when using light scattering additives to the pigment containing layer, which are preferably selected from transparent particles with a diameter in the low micrometre range, these act as scattering centers and can increase the hiding power of the pigmented layer by increasing its haze while showing no or only minor impact on its transmission, and can even show a positive impact on solar cell efficiency.

Moreover, it was surprisingly found that the concentration of the effect pigments in the layer, especially when used on the front side of a cover glass, can even be decreased when used in combination with light scattering additives selected from optical transparent particles, so that a possible impact of the effect pigments on the solar cell efficiency can even be further reduced.

For a typical application the concentration of the effect pigments should be ≥1 g/m² as otherwise the solar cell structure could be still visible while the color impression can already be strong. In addition to the higher hiding power, the angle dependency of the color of the solar cell module is reduced. In combination with the increased efficiency by the scattering particles themselves, this opens up new possibilities of designing colored solar cell modules while having an even less pronounced power loss by the partial reflection of light by the effect pigments.

It has been found that the layer containing the effect pigments and the light scattering additive according to the invention is ideal to provide sufficient color without significantly reducing the overall solar cell efficiency. Long term tests showed a high level of stability. As the direct contact between the effect pigment-containing film and the solar cell is the most demanding location in the setup of the solar module, it can safely be assumed that the effect pigment-containing film will also not show negative influence if used in any other position of the solar module stack.

The effect pigments are reflecting a part of the incident visible light, but are letting pass the light needed to create energy by the photovoltaic process. The effect pigments can be orientated such that it is possible to modify the angle of best efficiency and thus to play with color and efficiency.

The layer with the effect pigments and the light scattering additive can easily be applied to state of the art solar cells, making their application even more efficient. The process step of applying the layer containing the effect pigments and the light scattering additive to the solar cell module can easily be integrated into existing state of the art processes for manufacturing encapsulated solar cell modules.

By use of the present invention, the visual appearance of solar cells can be adapted to special needs. The exterior visual appearance of objects comprising solar cells such as buildings, devices, automotive vehicles, etc. can be improved and transparency and reflectivity of the solar cells can be controlled. Furthermore, visibility of the cells and the bright colored bus bars can be reduced or even avoided when a dark back sheet is used and the bus bars and connection points are darkened. Also, the invention can be used to provide solar cells with extraordinary colors to achieve special effects and designs, for example depending on the used effect pigment also a texture can be added such as e.g. a sparkle effect on the panels, mimicking brick walls or color shaded of different surfaces of material used in construction of houses.

Another advantage of the present invention is the possibility to seamlessly integrate solar cells into any surface by changing its appearance to a neutral look which people are used to many, for example into the surface of buildings (façade and roof), hand held, portable and installed devices, automotive vehicles or other transportation objects (cars, trucks, motorcycles, scooters, trains, ships, trailers etc.), price tags, plastics, wearable items and home appliances or similar, or any other highly visible surface that needs a seamless integration of solar cells without changing its optical appearance, or other kinds of solar installations, where the typical technical appearance of solar cells would change to a neutral look which people are used to, and where long-term stability is essential.

The coloration of the solar cells is possible over a variety of colors and not limited to a rigid substrate like glass or a single solar cell technology. Additionally, any complex solutions like additional layers in the lamination stack are not needed.

The effect pigment-containing layer renders appearance of solar cells' front surfaces to different colors, like e.g. red, blue, violet, green etc. and mixtures thereof. The thickness of the layer, the materials used therein, as well as the concentration of effect pigments or their combination may be varied to achieve the desired color effect. Especially with the combination/mixture of different concentrations of red, green and blue effect pigments a large color space/range can be achieved

Advantageously the light scattering centers can be incorporated into the same layer as the effect pigments which provide the coloring of the solar cell modules, which reduces the number of separate layers and renders the module production process more time- and cost-efficient.

Additionally, the costs of solar power are not increased in a significant way, because the efficiency of the colored solar cells is not impacted too heavily in contrast to currently available technologies which have the great drawback of an impact on the solar cell performance and where under real life conditions the efficiency of the solar cell may drop below 10% from an initial performance of >15%.

Surprisingly, effect pigments show the possibility to homogeneously color solar cells with a minor impact on cell efficiency if the concentration of the effect pigment is chosen accordingly. It has also surprisingly been found that especially conventional effect pigments such as pearlescent pigments, interference pigments and/or multi-layer pigments show the desired effects. As the working principle of these effect pigments is based on a selected reflection of a specific wavelength area, the color effect can be tuned selectively and the resulting efficiency can be directly correlated to the transmitted portion of light. In general, a desired color-effect can already be obtained at low reflections of a specific wavelength. The performance and efficiency of the solar cells can even be increased by appropriate selection of the pigments and the scattering additives as has been demonstrated in the examples below.

Moreover, it has been surprisingly found that the incorporation of light scattering centers does on the one hand provide a haze in the pigment containing layer according to the present invention, which advantageously reduces the appearance of dark patterns in the shape of the solar cell array structure or the electrical interconnects bus bars etc., but does on the other hand not significantly reduce the transmission of the pigment containing layer, and does thus not negatively affect the power conversion efficiency of the solar cell.

The light scattering centers in the layer according to the present invention are preferably selected from particles, bubbles, e.g. glass bubbles, droplets and density fluctuations in the pigment layer, all of which are capable of scattering light, more preferably from particles which are optically transparent or semi-transparent and can be organic or inorganic, hereinafter also referred to as “(light) scattering particles”.

Very preferably the light scattering particles in the layer according to the present invention are selected from SiO₂, preferably silica spheres or flour, spherical silicone resin powder, furthermore BaSO₄, Al₂O₃, BaMgAlOₓ or Eu-doped BaMgAlOₓ particles or glass bubbles.

Barium sulfate particles are commercially available for example from Sakai Chemical Industry Co., LTD. in various sizes, like the BMH series or the B series, such as BMH 40 or B-1.

Spherical silicone resin powder is commercially available for example from ABC NanoTech Co. Ltd. in various sizes, like for example E+508, E+520, E+540.

Glass bubbles are available for example from 3M in various sizes, like for example S60.

Silica flour is available for example from Sibelco in various size like for example M500 and M800.

The light scattering particles, such as the spherical silicone resin powder, preferably have globular shape, like spheres or granules, i.e. they are not platelet shaped. The light scattering particles preferably have an average particle size, preferably a medium particle size D50, of 0.1 to 10 μm, more preferably 0.2 to 8 μm, very preferably 0.5 to 6 μm, most preferably 1 to 4 μm. In another preferred embodiment the particles have an average particle size, preferably a medium particle size D50, of 2 to 10 μm, very preferably 3 to 6 μm.

In case of glass bubbles the medium particle size D50 is preferably in the range from 10 to 50 μm, more preferably in the range from 20 to 50 μm.

Preferably the concentration of the light scattering particles in the layer according to the present invention is in the range of 0.01 to 10%, more preferably 0.05 to 10%, even more preferably 0.05 to 5%, very preferably 0.05 to 3%, most preferably 0.1 to 1.5% by weight, and is preferably from 0.1 to 10 g/m².

The effect pigments in the layer according to the present invention are preferably selected from pearlescent pigments, interference pigments and multi-layer pigments. The effect pigments are preferably based on synthetic or natural mica, flake-form glass substrates, flake-form SiO₂ substrates or flake-form Al₂O₃ substrates. The flake-form substrate is preferably coated with one or more layers of metal oxides and/or metal oxide hydrates of Ti, Sn, Si, Al, Zr, Fe, Cr and Zn.

The effect pigments used in the layer in accordance with the present invention are preferably transparent or at least semi-transparent. The effect pigments useful for the invention exhibit preferably a red, blue or green color. However, other colors like, grey, white, violet, red or orange are also suitable. Other colors or their mixture to produce specific colors and shades can be used. The effect pigments can also produce metallic effects, such as but not limited to: silver, platinum, gold, copper and variety of other metals. It is also possible to create a printed images/pictures/shades of color using a mixture of different colors and a variation of thickness of layer.

The effect pigments preferably comprise, and very preferably consist of, a transparent or semi-transparent flake-form substrate coated with one or more layers of transparent or semi-transparent materials and optionally a post coating

Preferably the effect pigments contain a flake-form substrate which comprises at least one coating comprising a metal oxide, metal oxide hydrate or mixtures thereof. Preferably, the effect pigments consist of transparent or semi-transparent, colorless, flake-form substrates, which have been coated with one or more layers of transparent or semi-transparent, colorless materials. Preference is given to the use of pearlescent pigments, interference pigments, and/or multi-layer pigments. Long term stability of the effect pigments can preferably be improved with using a post coating of organic coatings and/or inorganic coatings as last layers of the effect pigments as described for example in WO 2011/095326 A1 and below.

Suitable substrates for the effect pigments are, for example, all known coated or uncoated, flake-form substrates, preferably transparent or semi-transparent, preferably colorless flakes. Suitable are, for example, phyllosilicates, in particular synthetic or natural mica, glass flakes, SiO₂ flakes, Al₂O₃ flakes, TiO₂ flakes, liquid crystal polymers (LCPs), holographic pigments, BiOCl flakes or mixtures of the said flakes. Aluminum flakes with dielectric coatings can also be used according to the invention at low concentrations to obtain a very high hiding power of the active photovoltaic layer.

The glass flakes can consist of all glass types known to the person skilled in the art, for example of A glass, E glass, C glass, ECR glass, recycled glass, window glass, borosilicate glass, Duran® glass, labware glass or optical glass. The refractive index of the glass flakes is preferably 1.45 to 1.80, in particular 1.50-1.70. Especially preferred glass flakes consist of A glass, C glass, E glass, ECR glass, quartz glass and borosilicate glass.

Preference is given to coated or uncoated flakes of synthetic or natural mica, SiO₂ flakes, Al₂O₃ flakes, and glass flakes, in particular glass flakes of C glass, ECR glass or calcium aluminum borosilicate. Especially, effect pigments based on calcium aluminum borosilicate glass are preferably used. In a variant of the invention Al₂O₃ flakes are preferred.

The substrates generally have a thickness of between 0.01 and 5 μm, in particular between 0.05 and 4.5 μm and particularly preferably from 0.1 to 1 μm. The length or width dimension is usually from 1 to 500 μm, preferably from 1 to 200 μm and in particular from 5 to 125 μm. They generally have an aspect ratio (ratio of mean diameter to mean particle thickness) of from 2:1 to 25,000:1, preferably from 3:1 to 1000:1 and in particular from 6:1 to 250:1. The said dimensions for the flake-form substrates in principle also apply to the coated effect pigments used in accordance with the invention, since the additional coatings are generally in the region of only a few hundred nanometers and thus do not significantly influence the thickness or length or width (particle size) of the effect pigments.

The particle size and the particle size distribution of the effect pigments and their substrates can be determined by various methods usual in the art. However, use is preferably made of the laser diffraction method in a standard process by means of a Malvern Mastersizer 2000, Beckman Coulter, Microtrac, etc. In addition, other technologies such as SEM (scanning electron microscope) images can be used.

In a preferred embodiment, the substrate is coated with one or more transparent or semitransparent layers comprising metal oxides, metal oxide hydrates, metal hydroxides, metal suboxides, metal fluorides, metal nitrides, metal oxynitrides or mixtures of these materials. Preferably, the substrate is partially or totally encased with these layers.

Furthermore, multilayered structures comprising high- and low-refractive-index layers may also be present, where high- and low-refractive-index layers preferably alternate. Particular preference is given to layer packages comprising a high-refractive-index layer (refractive index ≥2.0) and a low-refractive-index layer (refractive index <1.8), where one or more of these layer packages may have been applied to the substrate. The sequence of the high- and low-refractive-index layers can be matched to the substrate here in order to include the substrate in the multilayered structure.

Particular preference is given to metal oxides, metal oxide hydrates or mixtures thereof, preferably of Ti, Sn, Si, Al, Zr, Fe, Cr and Zn, especially of Ti, Sn and Si. Oxides and/or oxide hydrates may be present in a single layer or in separate layers. Particularly, titanium dioxide, in the rutile or anatase modification, preferably in the rutile modification is used. For conversion of titanium dioxide into the rutile modification, a tin dioxide layer is preferably applied beneath a titanium dioxide layer. Preferred multi-layer coatings comprise alternating high- and low-refractive-index layers, preferably such as TiO₂—SiO₂—TiO₂.

The layers of metal oxides, hydroxide and/or oxide hydrates are preferably applied by known wet-chemical methods, where the wet-chemical coating methods developed for the preparation of effect pigments, which result in enveloping of the substrate, can be used. After the wet-chemical application, the coated products are subsequently separated off, washed, dried and preferably calcined.

The thickness of the individual layers thereof is usually 10 to 1000 nm, preferably 15 to 800 nm, in particular 20 to 600 nm, especially 20 to 200 nm.

In order to increase the light, temperature, water and weather stability, the effect pigment may be subjected to post-coating or post-treatment. The post coating may be an organic coating and/or an inorganic coating as last layer/s. Post coatings preferably comprising one or more metal oxide layers of the elements Al, Si, Zr, Ce; Fe, Cr or mixtures or mixed phases thereof. Furthermore, organic or combined organic/inorganic post-coatings are possible. Silanes and/or organofunctional silanes may also be used, alone or in combination with metal oxides. Suitable post-coating or post-treatment methods are, for example, the methods described in DE 22 15 191, DE-A 31 51 354, DE-A 32 35 017 or DE-A 33 34 598, EP 0090259, EP 0 634 459, WO 99/57204, WO 96/32446, WO 99/57204, U.S. Pat. Nos. 5,759,255, 5,571,851, WO 01/92425, WO 2011/095326 or other methods known to the person skilled in the art man.

Effect pigments which can be used for the invention are, for example, the commercially available interference pigments or pearlescent pigments offered under the trade names Iriodin®, Pyrisma®, Xirallic®, Miraval®, Colorstream®, Spectraval®, RonaStar®, Biflair®, and Lumina Royal®. Other commercially available effect pigments may also be used. Especially, Colorstream®, Xirallic®, Miraval®, and Ronastar®, Pyrisma® pigments may be used.

In a preferred embodiment, the layer according to the present invention comprises a mixture of different effect pigments, more preferably two or more, very preferably three or more, different effect pigments. This enables to obtain special effects. In this preferred embodiment the effect pigments can be mixed in any proportion, but preferably the overall content of all effect pigments in the layer should not exceed 60% by weight.

In a very preferred embodiment, the layer according to the present invention comprises a mixture of red, green and blue effect pigments. Depending on the concentrations a large color space/range can thereby be achieved.

The concentration of the effect pigments in the layer according to the present invention is preferably in the range of 0.01 to 40%, preferably 0.01 to 20% by weight. More preferably, the concentration of the effect pigments in the layer according to the present invention is in the range of 0.01 to 15% by weight, particularly in the range of 0.1 to 10%, most preferably 0.1 to 8% by weight.

In another preferred embodiment the amount of effect pigment per m² of the layer according to the invention is in the range of 0.1 g/m² to 75 g/m², more preferably in the range of 0.2 to 30 g/m², very preferably 0.5 to 15 g/m², most preferably 0.5 to 6 g/m².

The layer according to the present invention containing the effect pigment(s) and the light scattering center(s) can in principle be selected from any suitable transparent material, including but not limited to polymer based, sol-gel based, polysilazane based, glass based or ceramic based layers.

In a preferred embodiment of the present invention the layer containing the effect pigment(s) and the light scattering center(s) is a polymer film.

Preferred polymer films are selected from polyolefin polymers or copolymers, in particular polyethylene polymers or copolymers, including but not limited to polyethylene, EVA (ethylene vinyl acetate), EBA (ethylene butyl acrylate), EMA (ethylene methyl acrylate), EEA (ethylene ethyl acrylate), POE (polyolefin elastomer), BPO (polyolefin copolymer), furthermore PVB or TPU (thermoplastic polyurethane), preferably EVA or polyethylene copolymers.

In another preferred embodiment of the present invention the layer containing the effect pigment(s) and the light scattering center(s) is a glass, ceramic or enamel layer. For this use the layer is preferably provided on a glass sheet or glass article.

The thickness of the layer containing the effect pigments and the light scattering centers is preferably in the range of 5 μm to 1000 μm, more preferably 20 μm to 800 μm, even more preferably 200 μm to 600 μm in case of polymer films, and preferably in the range from 10 μm to 300 μm for the ceramic layer, more preferable 20 μm to 200 μm, most preferably 30 μm to 100 μm in case of glass, ceramic or enamel layers.

The effect pigments and the light scattering particles can be incorporated into the layer according to the invention by methods known to the skilled person and described in the literature.

In case the layer according to the present invention is a glass, ceramic or enamel layer, it can be prepared for example by mixing the effect pigment(s) and light scattering particle(s) with glass frits or flux, ceramic or enamel precursor(s), placing the mixture onto a substrate and baking or firing the mixture at a temperature above the glass temperature of the glass frits, flux, ceramic or enamel, respectively.

Typical application methods of the precursor composition to the substrate include roller coating, screen printing or spraying of a mixture of flux, enamel or ceramic precursors, scattering and pigments in solvent e.g. water or glycol ether.

Especially in the decoration of glass articles, in particular glass plates, preferably a precursor composition is used which contains one or more pigments, one or more light scattering additives and one or more glass frits or flux. The precursor composition is baked after coating onto the substrate, whereby a glass-enamel containing the pigments and light scattering additives is formed. In the application of the precursor composition onto glass plates, the melt behaviour of the precursor composition should be adjusted according to typical conditions of the tempering process. Typical baking conditions are glass temperatures between approximately 580° C. and 650° C. and baking times of a few minutes. For colourful decoration of glass plates in architectural and instrument glass areas a good compatibility is required between the glass frit contained in the compositions with the inorganic pigments. The requirements of the baked compositions, i.e. of the glass-enamel, in many areas of use include a smooth run with short baking times at as low a temperature as possible, avoidance of cracks, good chemical resistance against acids and alkaline materials as well as good resistance to weathering. Preferred flux are Cadmium and Lead free flux with Si, Zn and B as main components e.g. based on borosilicate glass.

In case the layer according to the present invention is a polymer film, it can prepared by for example by extrusion methods such as melt extrusion of a polymer material wherein the effect pigment(s) and scattering particle(s) are added to the polymer melt before extrusion.

In extrusion, thermoplastics are melted to a viscous mass in a screw and then pressed into shape through a flat film die. The variety of possible shapes is huge. Films, foils, and plates are extruded through flat dies.

Masterbatches or compounds are usually used to color the molten mass with effect pigments and scattering particles. For a satisfactory result in plastic extrusion with effect pigments and additive, a balanced ratio must be maintained between the mixture energy and pigments and/or particles that are as undamaged as possible. Excessive shear from mixing sections or inappropriate screws or filters destroy effect pigments and dramatically decrease the pearl luster effect. The orientation of the pigments is critical for an even effect. This has to be ensured in the process through corresponding engineering and design of the machinery.

In a preferred embodiment of the present invention a masterbatch comprising the desired amount, e.g. 5 to 30% by weight, of the effect pigments and the scattering particles in the polymer material is added during the extrusion process of the polymer film. This can be done for example by creating a premix of the colored masterbatch pellets with the EVA pellets, or by any other known methods.

Due to the shear forces acting upon the effect pigments during the melt extrusion process the effect pigments are oriented substantially parallel to the encapsulant film surface.

In another preferred embodiment, the layer containing the effect pigment(s) and scattering particle(s) is a co-extruded film of two or more layers of the same or different polymer materials wherein one layer, preferably the layer facing the front sheet, contains one or more effect pigments.

EVA, employed as an encapsulant for the lamination of PV modules, is a thermoplastic polymer of which the formulation is especially adapted for use in solar applications. It brings high electrical insulation, transparency, flexibility and softness. In cross-linked formulations (like for encapsulants), it exhibits additionally high dimensional stability, fast curing and easy lamination. Common EVA formulations typically comprise, besides the polymer resin, a crosslinking agent, an adhesion promoter, a UV absorber, a UV stabilizer, and antioxidant agents. The crosslinking agent is a radical initiator-usually a peroxide-which decomposes under heat during the lamination and will form free radicals that initiate radicals on the polymeric backbone. The formed radicals will in turn lead to the formation of covalent bonds between the polymer chains.

The layer according to the invention does also allow to provide color shades or color patterns, such as for mimicking brick walls, which can be achieved e.g. by screen printing two different colors in the desired pattern, or color shades of different surfaces of material used in construction of houses, which can be achieved e.g. by spraying two different color shades into each other.

Impacts of pigments and layers onto c-Si solar cells can be assessed by reflection data. Reflection data are used to estimate max. power absorption/max. photo current generation of treated cells. Reflection and transmission measurements and calculations are conducted by common methods known to the person skilled in the art and as described further in the experimental section.

The haze of the layer containing the effect pigments and the light scattering centers can be determined from the transmission as described in Example 1.

The transmission of the layer comprising the effect pigments and the scattering additives is preferably ≥60%, more preferably ≥70%, very preferably ≥75%, most preferably ≥80% for light in the range from 500 to 800 nm, more preferably in the range from 450 to 900 nm, very preferably in the range from 400 to 1000 nm, most preferably in the range from 350 to 1150 nm.

The reflectance of the layer comprising the effect pigments and the scattering additives is preferably <40%, more preferably <30%, very preferably <25%, most preferably <20% for light in the range from 450 to 800 nm, more preferably in the range from 400 to 1000 nm, most preferably in the range from 300 to 1150 nm.

The haze of the layer comprising the effect pigments and the scattering additives is preferably ≥50%, more preferably ≥60%, very preferably ≥70%, most preferably ≥80% for light in the range from 500 to 800 nm, more preferably in the range from 450 to 900 nm, most preferably in the range from 350 to 1150 nm.

The present application also relates to the use of a layer as described above and below as coloring layer, in particular as coloring encapsulant layer, in any type of device collecting and converting solar energy, such as solar thermal or photovoltaic device, including but not limited to organic photodiodes, solar cells or solar cell modules, which can be organic, inorganic or hybrid types.

The present application further relates to device collecting and converting solar energy, such as solar thermal or photovoltaic device, including but not limited to organic photodiodes, solar cells or solar cell modules, which can be organic, inorganic or hybrid types, comprising a layer according to the present invention as described above and below.

A preferred solar cell or solar cell module according to the present invention comprises the following components:
1) a transparent front sheet, preferably of glass or plastic film like for example Polycarbonate, Plexiglas, TPT (Tedlar®-Polyester-Tedlar®, wherein Tedlar® is a PVF (polyvinylfluoride) film commercially available from DuPont),
2) optionally one or more further transparent layers at the front side of the solar cell, which are preferably selected from polymer films, or ceramic layers provided on a front glass sheet, and which may also serve as encapsulation film or front sheet,
3) a solar cell or a string or array of electrically interconnected solar cells 4) optionally one or more further layers at the rear side of the solar cell, which are preferably selected from polymer films,
5) a rear sheet, preferably of glass or a plastic film like for example polycarbonate, Plexiglas, TPT (Tedlar®-Polyester-Tedlar®, wherein Tedlar® is a PVF (polyvinylfluoride) film commercially available from DuPont),
wherein the front sheet of component 1) comprises one or more effect pigments and one or more light scattering centers as described above and below, or the solar cell or solar cell module comprises a further front side transparent layer as component 2) which comprises one or more effect pigments and one or more light scattering centers as described above and below.

The components are stacked in following sequence: 1) front sheet, 2) optional further transparent layer(s) at the front side, 3) solar cell(s), 4) optional further layer(s) at the rear side, 5) rear sheet.

A solar cell module according to the preferred embodiment of the present invention is exemplarily and schematically illustrated in FIG. 1 and includes a transparent front sheet (11), which is preferably a glass sheet, a transparent layer according to the invention (12) containing the effect pigment(s) and the light scattering center(s), an array of solar cells with bus bars (13), and a rear sheet (14), which is preferably black or of dark color. The arrow indicates the direction of the incident light.

In a preferred embodiment, one or more further encapsulant films (not shown in FIG. 1), are provided between the pigment containing layer (12) and the solar cells (13), and/or between the solar cells (13) and the rear sheet (14). The further encapsulant film(s) do not contain effect pigments or light scattering centers.

In another preferred embodiment (not shown in FIG. 1), the solar cell module does not contain the front sheet (11), and the transparent layer (12) containing the effect pigments and the light scattering centers is serving as front sheet.

In another preferred embodiment (not shown in FIG. 1), the layer (12) containing the effect pigments and the light scattering centers is serving as encapsulant film.

In another preferred embodiment (not shown in FIG. 1), a protective foil or an exterior foil is applied on top of the finished solar cell or solar cell module.

The components located at the front side of the solar cell module, like the front sheet (11), the layer film (12) and optional further front encapsulant films are substantially transparent to incident light passing through to the solar cell or solar cell array (13).

The front sheet (11) and rear sheet (14) are preferably selected from glass sheets. In another preferred embodiment, the front sheet (11) and/or the rear sheet (14), more preferably the rear sheet (14), is a polymer sheet, preferably a TPT or polycarbonate sheet.

The polymer films at the front and rear side are preferably selected from organic polymers including but not limited to polyolefins like for example polyethylene polymers or copolymers such as polyethylene, EVA (ethylene vinylacetate), EBA (ethylene butylacrylate), EMA (ethylene methylacrylate), EEA (ethylene ethylacrylate), POE (polyolefin elastomer), BPO, furthermore polyesters, polyamides, polyurethanes, polyvinylbutyral PVB, polycarbonates, polyvinylchloride, polyvinyl acetate, polyacrylates, polyols, polyisocyanates or polyamines, as well as copolymers, resins, blends or multilayers of the aforementioned, such as polycarbonate-containing urethane resins, vinyl chloride-vinyl acetate containing urethane resins, acrylic resins, polyurethane acrylate resins, polyester resins, or TPU (thermoplastic polyurethane).

If the front transparent layer is a polymer film, it is preferably selected from polyolefin polymer or copolymer films, very preferably from polyethylene polymer or copolymer films, in particular from EVA, EBA, EMA, EEA, POE, BPO, PVB or TPU films, most preferably from polyethylene copolymer or EVA films.

Further preferred polymers for use as or in rear sheets can be categorized into double fluoropolymers, single fluoropolymers and non-fluoropolymers and various constructions within each category. Double fluoropolymer rear sheets do typically consist mainly of outer layers of Tedlar® polyvinyl fluoride (PVF) films, or Kynar® polyvinylidene fluoride (PVDF) films, and a core layer of polyethylene terephthalate (PET). Single fluoropolymer rear sheets do typically consist of Tedlar or Kynar® on the air side and PET and primer or EVA layers on the inner side. Non-fluoropolymer rear sheets do typically consist of two PET and one primer or EVA layers.

The solar cell array (13) as exemplarily shown in FIG. 1 may also be replaced by a single solar cell.

The solar cells (13) can be selected from any kind of solar cell technologies including amorphous, mono- and multi crystalline silicon solar cells, CIGS, CdTe, III/V solar cells, II/VI solar cells, perovskite solar cells, organic solar cells, quantum dot solar cells and dye sensitized solar cells, as well as solar cell modules made out of single cells. Crystalline solar cells include cell structures like Al-BSF, PERC, PERL, PERT, HIT, IBC, bifacial or any other cell type based on crystalline silicon substrates.

The rear sheet (14) is preferably black or of a dark color, and/or a black or dark colored sheet like e.g. the rear encapsulant film or an additional encapsulant film is provided at the rear side of the solar cell or solar cell module, i.e. between the solar cells (13) and the rear sheet (14), wherein the dark color is preferably a dark blue equal to the color of solar cells.

In the solar cells (13) the conducting parts preferably comprise metal based conducting parts including but not limited to the following parts:
i) the H-grid consisting of main vertical connectors—so called bus bars,
ii) the horizontal current gathering parts—so called fingers,
iii) connectors and solder between the cells,

In a preferred embodiment of the invention, in order to achieve a fully homogeneous appearance of the solar cells (13) the metal based conducting parts, including but not limited to the aforementioned parts i) to iii), are preferably colored black or in a dark color like dark solar blue prior to the application of the layer (12) with the effect pigments and the light scattering centers.

In another preferred embodiment of the invention, a grid of dark color, preferably black or dark blue, is incorporated into one or more layers of the solar cells, said grid covering bright areas like the space between the single solar cells and the conducting parts including bus bars, conducting path and soldering points. In another preferred embodiment of the invention, to hide the space between the single solar cells, a black or dark blue back layer is applied behind the solar cells. The black or dark blue back layer can be printed or applied as a foil.

Suitable and preferred ways of darkening the else white appearing metal parts of the solar cells (13) with a H-grid front pattern include covering the metal stripes with a black polymer foil or brushing the metal parts with a black paint. In the case of a printed silver H-grid the silver can directly be blackened by formation of a thin layer of silver-sulphide (for example by treatment with H₂S) or by plating and oxidation of copper. In the case of a plated metal grid the top layer of the metal stack can directly be plated with a strongly absorbing metal oxide or sulphide like CuO or Ag₂S or similar dark colored metal oxides or others. In the case of the usage of novel metallization schemes (like the smart wire technology) blackened wires or wires with a microstructure reducing the reflectance and thus making a dark appearance of the metal grid can also be used according to the invention. If a black or dark solar blue rear sheet is used as module background, a very homogeneous appearance of the whole module even from a close distance can be achieved.

The front, rear and further encapsulant films preferably contain, very preferably consist of TPU or a polyolefin including but not limited to EVA, EBA, EMA, EEA, POE or BPO, most preferably EVA.

The layer (12) containing the effect pigment(s) and the light scattering centers is located at the radiation-receiving side, i.e. within the visible parts of the solar cells or solar cell modules according to the present invention. It may be located in the solar cell module on the inside of the front sheet (11), i.e. the side facing the solar cell or array of solar cells, as shown in FIG. 1, or alternatively it may be located on the outside of the front sheet (11), i.e. the side facing the incident light.

If a pigmented ceramic layer according to the invention is used on the outer (weather facing) surface of a cover glass, preferably a transparent, protective layer is added. This protective layer can be based for example on CVD layers of oxides or wet coated films e.g. of polysilazanes.

The layer (12) with the effect pigments and the light scattering centers can be locally and flexibly applied on any surface. Thus, it can be applied on the exterior of a finished solar cell or solar cell module, on the protective substrate covering the solar cell or solar cell module (glass or plastic), or directly on the photoactive material/solar cells.

Advantageously, the layer (12) with the effect pigments and the light scattering centers can also be used as anti-reflective film.

The solar cell module or solar cell modules according to the present invention can be prepared by processes known to the skilled person and described in the literature.

If the layer with the effect pigments and the light scattering centers is a glass, ceramic or enamel layer, it is preferably prepared on a glass substrate as described above, and the glass substrate covered by the layer with the effect pigments and the light scattering centers is then provided on the other individual components or layers of the solar cell module as described above and below which are stacked in the desired sequence. The ceramic layer or enamel layer with effect pigments and light scattering centers on the glass substrate can be incorporated into the solar cell or can form an outside layer. If it forms an outside layer, it is preferably protected by a protective layer. The protective layer can be applied on top of the colored enamel or ceramic layer.

If the layer with the effect pigments and the light scattering centers is a polymer film, preferably said polymer film and the other individual components or layers of the solar cell module as described above and below are stacked in the desired sequence and then laminated together e.g. by applying heat and/or pressure, or using an adhesive or a binding agent.

Alternatively the lamination process of preparing the solar cell module or solar cell modules can also be carried out in two steps, such that the layer containing the effect pigments and the light scattering centers is laminated to the front sheet in a first lamination (or pre-lamination) step, and then the front sheet plus the laminated layer containing the effect pigments and the light scattering centers is laminated to the stack of the remaining components in a second lamination step.

A preferred process for preparing a colored solar cell or colored solar cell module according to the present invention thus comprises the following steps:
a) lamination of a layer, preferably a polymer film, containing one or more effect pigments and one or more light scattering centers to a front sheet, preferably by applying heat and/or pressure, or using an adhesive or a binding agent or layer, preferably in a vacuum press,
b) optionally cooling down the front sheet with the laminated layer containing the effect pigments and the light scattering centers, preferably to room temperature,
c) providing a stack comprising the following layers
   C1) optionally one or more front encapsulant films,
   C2) one or more solar cells, or an array of solar cells which are electrically interconnected by conducting parts, preferably by bus bars,
   C3) optionally one or more rear encapsulant films,
   C4) a rear sheet,
on top of the front sheet with the laminated layer containing the effect pigments and the light scattering centers, or providing the front sheet with the laminated layer containing the effect pigments and the light scattering centers on top of the stack of layers C1 to C4,
d) laminating the stack of layers C1 to C4 to the front sheet with the laminated layer containing the effect pigments and the light scattering centers, preferably by applying heat and/or pressure, or using an adhesive or a binding agent, preferably in a vacuum press.

The lamination steps, like steps a) and d) above, can be carried out by using standard methods, e.g. subjecting the two layers to heat and pressure, e.g. by applying a vacuum and/or any other form of physical pressure, for a certain time interval, e.g. in a lamination machine.

Alternatively and/or additionally lamination can be achieved or supported by using one or more adhesives and/or bonding agents or layers. Adhesives/bonding agents can be reactive or non-reactive and can comprise or consist of natural, or synthetic origin. Suitable and preferred examples include, without limitation, polyurethane (PUR), thermoplastic polyurethane (TPU), rubber, acrylic and silicone adhesives, depending on the desired application.

After the first or pre-lamination step a), in case heat was applied for lamination, the front sheet with the laminated layer containing the effect pigments and the light scattering centers is preferably cooled down in step b), very preferably to room temperature. The layer containing the effect pigments and the light scattering centers is now permanently fixed to the glass and cannot be pulled off by hand. The pigments are evenly distributed on the surface.

In step c) the remaining stack of optional front encapsulant, solar cells, optional rear encapsulant, and rear sheet is placed on top of the pre-laminated bilayer of the front glass and the layer with the effect pigments and the light scattering centers, or alternatively the pre-laminated bilayer is placed on top of the remaining stack. Preferably the pre-laminated bilayer is placed such the layer with the effect pigments and the light scattering centers is facing the solar cells.

Then the final lamination of the stack is carried out in step d) under conditions which are preferably similar to those of the pre-lamination step.

In the lamination steps, like steps a) and d) above, the suitable applied heat and pressure and the time interval depend on the type of sheets and films used and can be easily chosen by the person skilled in the art. In case a front glass sheet and a polymer film of EVA are used, preferably the heating temperature is in the range of 130° C. to 160° C., very preferably ca. 135° C., and the time interval is preferably 20 to 30 minutes. Preferably a vacuum press is used. Preferably a pressure of 400 to 900 mbar is applied.

After the final lamination step d) the laminated stack is cooled down again, preferably to room temperature. Excessive material of the encapsulant films and rear sheets (in case a plastic rear sheet is used) can be cut away and a junction box can be attached for electrical connection of the solar cell module. Finally the laminate can be framed.

After the lamination step(s) the film thickness will usually be reduced depending on the lamination conditions.

Preferably the resulting laminate is completely sealed and, in the ideal case, can protect the solar cells for at least 25 years.

Preferably the solar cells and solar cell modules according to the present invention show a power change ΔP of >−5%, more preferably >−2%, very preferably >0.1%, wherein

$$Δ P ( \% ) = \frac{{P}_{i} - {P}_{ref}}{{P}_{ref}} \times 100$$

and Pᵢ is the power of a solar cell or solar cell module SCᵢ according to the present invention with a layer comprising the effect pigments and scattering centers as described above and below, and P_{ref} is the power of a reference solar cell or solar cell module SC_{ref} having the same components as SCᵢ except that the layer with the effect pigments does not contain light scattering centers. A negative value of ΔP thus indicates a power loss and a positive value of ΔP indicates a power gain vs. the reference.

The following examples are intended to explain the present invention without restricting it.

### Example 1—Polymer Films with Effect Pigments and Scattering Particles

### Film Preparation

Different polyethylene films according to the invention were prepared containing 0.15% of the effect pigment Iriodin® 7235 Ultra Rutile Green Pearl, resulting in a concentration of 1 g/m² of effect pigment, and further containing in each case one type of the light scattering particles listed below.

a) 1% barium sulfate BMH-40 particles with a medium particle size D50 of 5 μm
b) 1% barium sulfate B-1 particles with a medium particle size D50 of 0.5 μm
c) 1% spherical silicone resin powder E+508 with a medium particle size D50 of 0.8 μm
d) 1% spherical silicone resin powder E+520 with a medium particle size D50 of 2 μm
e) 1% spherical silicone resin powder E+540 with a medium particle size D50 of 4 μm
f) 0.5% spherical silicone resin powder E+520 with a medium particle size D50 of 2 μm
g) 2% spherical silicone resin powder E+520 with a medium particle size D50 of 2 μm
h) 0.5% spherical silicone resin powder E+540 with a medium particle size D50 of 4 μm
i) 2% spherical silicone resin powder E+540 with a medium particle size D50 of 2 μm
j) 1% glass bubbles S60 with a medium particle size of 30 μm.

All added particles, while being light scattering, are as such optically transparent.

For comparison purposes, a reference film was prepared as described above containing 0.15% of the effect pigment Iriodin® 7235 Ultra Rutile Green Pearl but without the addition of any scattering particles.

While encapsulant films are usually prepared via extrusion of casts films, for practical reasons in the present examples film samples with a size 10×15 cm and a thickness of 700 μm were prepared via injection moulding of a polyethylene resin containing the pigment and the particles as follows:

An injection-moulding machine of the Kraus-Maffei CX-130-380 type was used. After closing of the mould, a transparent plastic melt (Evatane® 28-25PV, product from Arkema) was injected into the injection mould. The injection operation was carried out at a temperature in the range from 180 to 200° C. and a pressure in the range from 450 to 900 bar (4.5×10⁷ N/m² to 9×10⁷ N/m²). For coloring the plastic melt or adding the scattering particles, a masterbatch was used accordingly in the required concentration. The polymer film can be embossed in a post-step when needed. Embossing structure usually support removal of air during lamination step of solar modules.

### Transmission and Haze Measurements

The transmission of the films according to the invention and of the reference film was measured in a Cary UV/Vis spectrometer equipped with an Ulbrich sphere (after ASTM D1003). The haze of the films according to the invention and of the reference film was calculated from the transmission measurements via the following equation:

$$Haze ( \% ) = ( ( T 4 / T 2 ) - ( T 3 / T 1 ) ) \cdot 100$$

wherein T1 represents the reference for incoming light with no sample in the sample holder and a reflection standard at the measurement position, T2 the transmitted light through the examined sample with the sample in the sample holder and a reflection standard at the measurement position (measuring only the light directly transmitted through the sample), T3 measuring the reference scattered light from the spectrometer itself having no sample in the holder and no reflection standard at the measurement spot and T4 measuring the scattered light from the spectrometer and the sample having the sample in the sample holder and no reflection standard at the measurement spot (measuring all light transmitted through the sample).

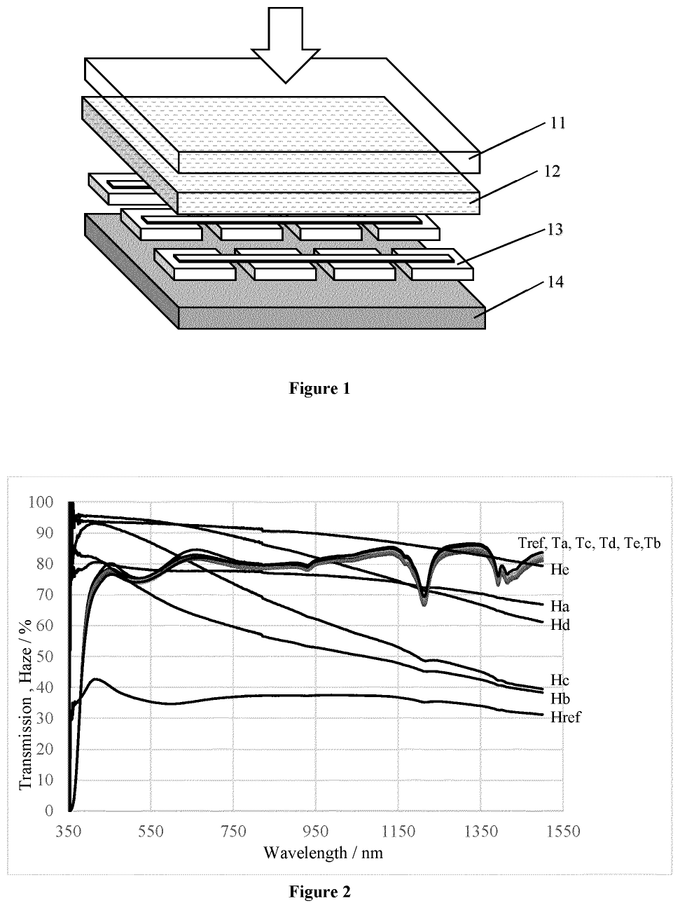

FIG. 2 depicts the corresponding transmission values (graphs Ta etc.) as well as the corresponding haze values (graphs Ha etc.) for the films a) to e) according to the invention with scattering particles as listed above of different size and type (Ta-e, Ha-e), and for the reference film without any additional scattering particles (Tref, Href).

From FIG. 2 it can be seen that the films with the scattering particles show good haze, especially in the visible range, compared to the reference film. It can also be seen that the haze increases with increasing scattering particle size while there is only little influence of the scattering particles on the transmission of the films.

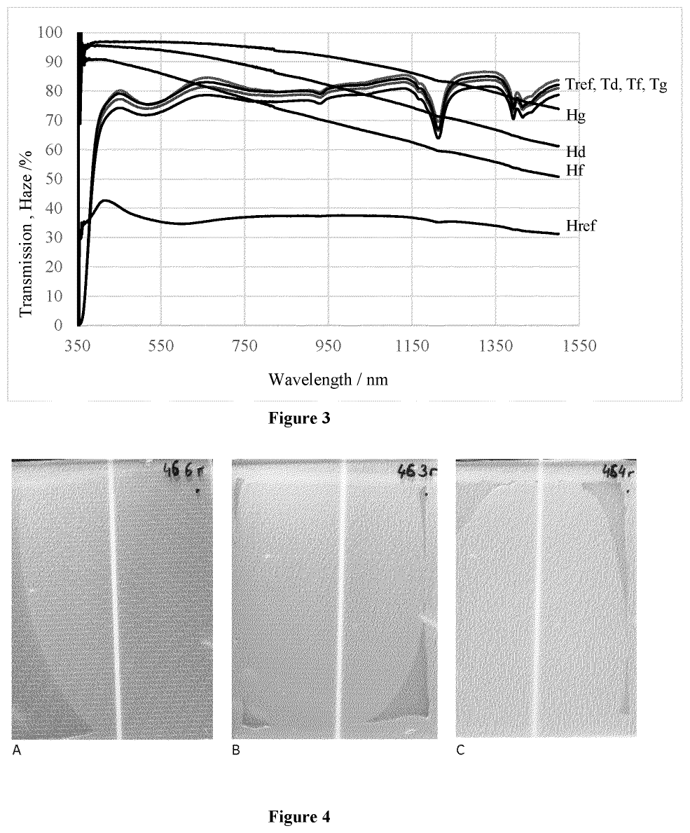

FIG. 3 depicts the corresponding transmission values (graphs Td etc.) as well as the corresponding haze values (graphs Hd etc.) for the films d), f) and g) according to the invention with scattering particles E+520 at different concentrations (Td, Tf, Tg, Hd, Hf, Hg), and for the reference film without any additional scattering particles (Tref, Href).

From FIG. 3 it can be seen that the films with the scattering particles show good haze, especially in the visible range, compared to the reference film. It can also be seen that the haze increases with increasing scattering particle concentration while there is only little influence of the scattering particles on the transmission of the films.

### Use of Polymer Films as Solar Cell Encapsulant

The films c), d) and e) according to the invention with 1% of the spherical silicone resin powder E+508, E-520 and E-540, respectively, of different size and the reference film were each provided as encapsulant over a solar cell on a solar flasher and the impact on the solar cell efficiency was measured using a Wavelab Sinus 7 solar simulator.

For measuring the output performance conformity of the solar PV module a flash test machine (solar flasher or sun simulator) was used. During the flash test the PV module is exposed to a short (1 ms to 30 ms), bright (100 mW per sq. cm) flash of light from a xenon filled arc lamp. The output spectrum of this lamp is selected to be as close to the spectrum of the sun as possible. The output is collected by a computer and a voltammeter, and the data can be compared to a reference solar module

The results are shown in Table 1 below.

TABLE 1
Efficiency of Solar Cells

| | | | | Δ Power vs. |
|---|---|---|---|---|
| Film Sample | Voltage/V | Current/mA | Power/mW | Reference/% |
| Reference | 0.6132 | 50.94 | 31.23 | n.a. |
| c) 1% E + 508 | 0.6113 | 49.75 | 30.41 | −2.63 |
| d) 1% E + 520 | 0.6114 | 50.87 | 31.10 | −0.43 |
| e) 1% E + 540 | 0.6121 | 50.82 | 31.10 | −0.41 |

From Table 2 it can be seen that the smaller particles with 0.8 μm particle size have a small influence and the larger particles d) and e) with 2 or 4 μm particle size have a very small influence on the solar efficiency. At the same time, FIG. 2 showed that these particles lead to films with increased haze and only slight decrease of the transmission.

In order to investigate the influence effect of the scattering particles concentration, the films d)-i) according to the invention and the reference film were each provided as encapsulant over a solar cell on a solar flasher and the impact on the solar cell efficiency was measured using a Wavelab Sinus 7 solar simulator as described above.

The results are shown in Table 2 below.

TABLE 2
Efficiency of Solar Cells

| | | | | Δ Power vs. |
|---|---|---|---|---|
| Film Sample | Voltage/V | Current/mA | Power/mW | Reference/% |
| Reference | 0.6132 | 50.94 | 31.23 | n.a. |
| f) 0.5% E + 520 | 0.6127 | 51.15 | 31.34 | +0.33 |
| d) 1.0% E + 520 | 0.6114 | 50.87 | 31.10 | −0.43 |
| g) 2.0% E + 520 | 0.6116 | 50.35 | 30.79 | −1.42 |
| h) 0.5% E + 540 | 0.6125 | 51.02 | 31.25 | +0.04 |
| e) 1.0% E + 540 | 0.6121 | 50.82 | 31.11 | −0.41 |
| i) 2.0% E + 540 | 0.6113 | 50.51 | 30.88 | −1.15 |

From Table 2 it can be seen that in all cases the particles have only little influence on the solar efficiency, and that with increasing particle concentration the effect is more pronounced. Surprisingly it can also be seen that for small particle concentrations the solar cell efficiency is even increased compared to the reference. This might be attributed to a better absorption of scattered photons by the solar cell which can be seen in the increased photocurrent.

Overall, the above results for the transmission and haze values of the films on the one hand, and the efficiency data of solar cells containing the films as encapsulant on the other hand, demonstrate that the addition of the scattering particles to the pigment containing film provides the desired haze with only slightly reduced the transmission, while on the other hand the solar cell efficiency is not significantly affected or even slightly improved.

### Example 2—Polymer Films with Effect Pigments and Scattering Particles

### Film Preparation

In order to examine the influence of the scattering additive on the optical appearance of the solar cell structure as well as the efficiency, a glass sample was prepared consisting of 2 glass panels of 3 mm thickness laminated with an extruded EVA film of 700 μm thickness, containing 0.15% (or 1 g/m²) of the effect pigment Iriodin® 7235 Ultra Rutile Green Pearl as well as scattering additive selected from barium sulfate particles BMH-40 (D50 of 5 μm) or barium sulfate particles B-1 (D50 of 0.55 μm) or glass bubbles S60 (D50 of 30 μm), in a concentration of 1% or 2%.

For comparison purposes, a reference film was prepared as described above with 0.15% of the pigment Iriodin® 7235 Ultra Rutile Green Pearl but without any additional scattering particles.

### Transmission and Haze

FIG. 4 shows optical images of the resulting films without scattering particles (A) and with 1% (B) or 2% (C) of scattering particles BMH-40 against a background of a laminated solar cell with a front glass. It can be seen that the films with scattering particles show a haze that renders the background less visible (B) or virtually invisible (C).

### Use of Polymer Films as Solar Cell Encapsulant

In order to examine the impact on the efficiency the films were tested using a flash test machine put on a commercially available perovskite single solar cell. As light source a controlled set of LEDs providing a spectral range of 350 nm to 1100 nm was used and the power output was measured using a Wavelab Sinus 7 solar simulator and a voltammeter.

The results are shown in Table 3 below.

TABLE 3
Efficiency of Solar Cells

| | | | | Δ Power vs. |
|---|---|---|---|---|
| Film Sample | Voltage/V | Current/mA | Power/mW | Reference/% |
| Reference | 0.6132 | 50.94 | 31.23 | n.a. |
| a) 1% BMH-40 | 0.6102 | 50.54 | 30.84 | −1.20 |
| b) 1% BMH-1 | 0.6092 | 49.98 | 30.45 | −2.50 |
| j) 1% S60 | 0.6118 | 50.98 | 31.19 | −0.13 |

From Table 3 it can be seen that the addition of the particles has only a slightly negative impact on the cell efficiency.

Overall, the results demonstrate that the addition of the scattering particles to the pigment containing film provides the desired haze, while on the other hand the solar cell efficiency is not significantly affected or even slightly improved.

### Example 3—Enamel Layers with Effect Pigments and Scattering Particles

### Layer Preparation

Enamel layers were printed on a glass plate using a hand screenprinter with 48 mash screen giving a film thickness of 36 μm. The enamels used are standard enamels from the ceramic industry and contained 2% Iriodin® 7235 Ultra Rutile Green Pearl or Iriodin® 7225 Ultra Rutile Blue Pearl as a coloring pigment, resulting in a pigment concentration of ca. 1.4 g/m² in the dried film. In addition silica flour with different particle sizes was added and the haze as well as the transmission was measured. The particles used were a quartz powder with an average diameter D50 of 4 μm (M500) at a concentration of 0.5% in the paste or 0.4 g/m² in the dried film, or quartz powder with an average diameter D50 of 1.8 μm (M800) at a concentration of 0.5% in the paste or 0.4 g/m² in the dried film. The films were afterwards fired in a fast firing furnace to a glass temperature of 620° C. to melt the enamel leaving a clear glass layer containing the pigments and the silica flour.

For comparison purposes, reference enamel layers were prepared as described above with the same pigment concentration but without any additional scattering particles.

The pigment and particle concentrations in the individual layers are listed below in Table 4.

TABLE 4
Pigment and Particle Concentrations

| | | Pigment | | Scattering |
|---|---|---|---|---|
| | | Concen- | Scattering | Particle |
| Sample No. | Pigment | tration | Particle | Concentration |
| Reference 1 | Iriodin ® 7235 | 2% | — | — |
| 1 | Iriodin ® 7235 | 2% | M500 | 0.5% |
| 2 | Iriodin ® 7235 | 2% | M800 | 0.5% |
| Reference 2 | Iriodin ® 7225 | 2% | — | — |
| 3 | Iriodin ® 7225 | 2% | M500 | 0.5% |
| 4 | Iriodin ® 7225 | 2% | M800 | 0.5% |

### Transmission and Haze Measurements

The transmission and haze of the glass plate with the enamel layers 1˜4 containing the effect pigments and silica flour according to the invention, and of the glass plate with the reference enamel layers Ref1 and Ref2 containing only the effect pigments, were measured and calculated as described in Example 1.

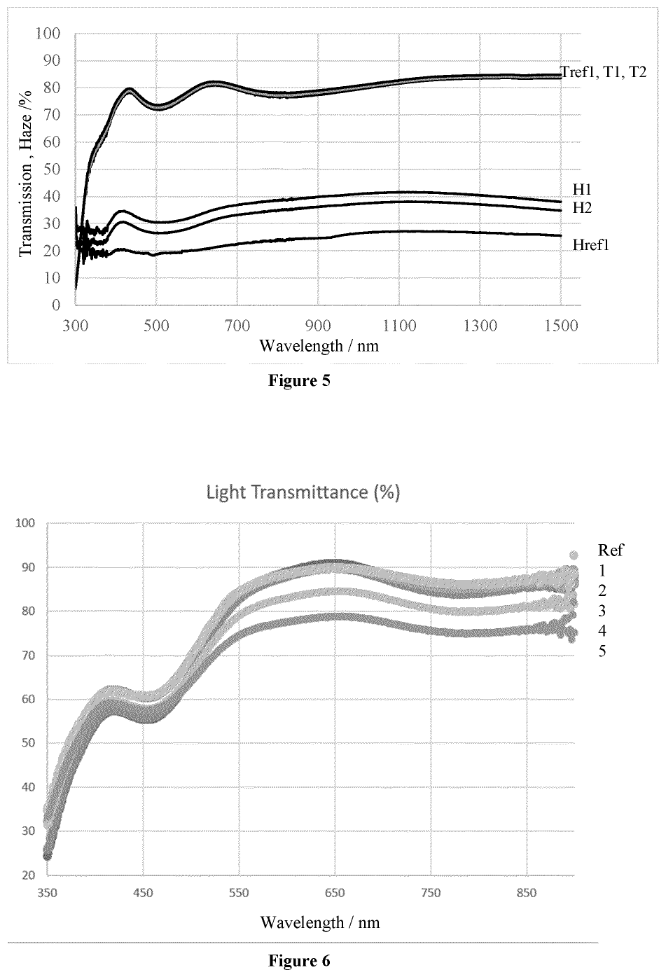

FIG. 5 depicts the corresponding transmission and haze values for the glass plates with layers 1 and 2 according to the invention (T1-2, H1-2), and for the glass plates with reference layer (Tref1, Href1).

From FIG. 5 it can be seen that the scattering particles do not change the transmission of the enamel layers but increase their haze, compared to the reference layers.

### Use of Enamel Layers as Solar Cell Encapsulant

The glass plates with the enamel layers 1-4 according to the invention and reference layers 1 and 2 were put over a solar cell on a solar flasher and the impact of the enamel layers on the solar cell efficiency was measured as described in Example 1.

The results are shown in Table 5 below.

TABLE 5
Efficiency of Solar Cells

| | | | | Δ Power vs. |
|---|---|---|---|---|
| Sample No. | Voltage/V | Current/mA | Power/mW | Reference/% |
| Reference 1 | 0.6078 | 49.52 | 30.1 | n.a. |
| 1 | 0.6121 | 50.28 | 30.78 | +2.2 |
| 2 | 0.6134 | 50.34 | 30.88 | +2.5 |
| Reference 2 | 0.6079 | 49.71 | 30.22 | n.a. |
| 3 | 0.6126 | 50.39 | 30.87 | +2.1 |
| 4 | 0.6128 | 50.49 | 30.94 | +2.3 |

From Table 5 it can be seen that the power output was not negatively affected but instead increased by adding the scattering particles in all cases. This may be attributed to the light scattering by the particles which leads to a better absorption of light quants by the solar cell as the light does not hit it in a steep angle after being scattered.

Overall, the results demonstrate that the addition of the scattering particles to the pigment containing enamel layer provides the desired haze, while on the other hand the solar cell efficiency is not significantly affected but instead even improved.

### Example 4—Coatings with Effect Pigments and Scattering Particles

### Coating Preparation

A spraycoating formulation was applied to a cover glass of a solar module. The formulation consisted of a 20% solution of polysilazane as a binder in butylacetate as a solvent with the effect pigment Xirallic® T-60-23 in a concentration of 6% in the solution. The scattering particles used were barium sulfate particles BMH-40 with an average particle diameter D50 of 5 μm. Different formulations were prepared wherein the concentration of the particles was varied between 0 and 3%. Each formulation was manually applied with standard spraycoating equipment and dried at 200° C. for 2 hours after application.

The coated film thickness was in all cases selected to give a pigment concentration of 2 g/m².

For comparison purposes, reference coatings were prepared as described above with the same pigment concentration but without any additional scattering particles.

The pigment and particle concentrations in the individual films are listed below in Table 6.

TABLE 6
Pigment and Particle Concentrations

| | | | | Scattering |
|---|---|---|---|---|
| | | Pigment | Scattering | Particle |
| Sample No. | Pigment | Concentration | Particle | Concentration |
| Reference | Xirallic ® T-60-23 | 6% | — | — |
| 1 | Xirallic ® T-60-23 | 6% | BMH-40 | 1% |
| 2 | Xirallic ® T-60-23 | 6% | BMH-40 | 2% |
| 3 | Xirallic ® T-60-23 | 6% | BMH-40 | 3% |
| 4 | Xirallic ® T-60-23 | 6% | BMH-40 | 6% |
| 5 | Xirallic ® T-60-23 | 6% | BMH-40 | 12% |

### Transmission and Haze Measurements

After the drying step the transmission of the coated samples was measured with a Cary Photo spectrometer and an Ulbricht-sphere as described in Example 1.

FIG. 6 depicts the transmission values for the coated samples.

From FIG. 6 it can be seen that up to a concentration of 3% the scattering particles, while showing an increased hiding power of any structure behind the glass, do not reduce the total transmission.

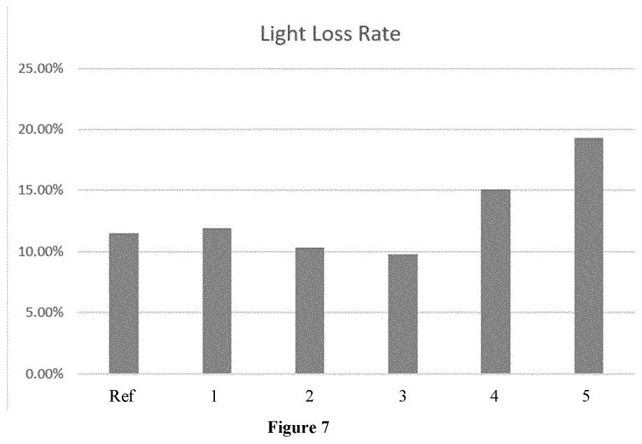

FIG. 7 depicts the light loss rate for the coated samples obtained by integrating the transmission curves of FIG. 6.

From FIG. 7 it can be seen that the light loss rate shows a decrease up to a concentration of the scattering particles of 3%.

The results demonstrate that the layers according to the present invention enables the efficient coloring of solar cell modules with an additional haze that prevents the appearance of undesired shadows or patterns through the coloured layer, without a significant negative impact, or even a positive impact, on the solar cell efficiency.

1. A layer, sheet or film comprising one or more effect pigments comprising a transparent or semi-transparent flake-form substrate coated with one or more layers of transparent or semi-transparent materials and optionally a post coating, and further comprising one or more light scattering centers.

2. The layer, sheet or film according to claim 1, wherein the light scattering centers are selected from particles, bubbles, droplets and density fluctuations.

3. The layer, sheet or film according to claim 1, wherein the light scattering centers are selected from organic or inorganic particles which are transparent or semi-transparent.

4. The layer, sheet or film according to claim 1, wherein the light scattering centers are selected from SiO₂, silica spheres or flour, spherical silicone resin powder, BaSO₄, Al₂O₃, BaMgAlOₓ or Eu-doped BaMgAlOₓ particles or glass bubbles.

5. The layer, sheet or film according to claim 1, wherein the concentration of the light scattering centers in the layer is in the range of 0.01 to 5% by weight.

6. The layer, sheet or film according to claim 1, wherein it has a transmission of ≥70% for light in the range from 400 to 1000 nm.

7. The layer, sheet or film according to claim 1, wherein it has a haze of ≥50% for light in the range from 400 to 1000 nm.

8. The layer, sheet or film according to claim 1, wherein the effect pigments are selected from pearlescent pigments, interference pigments and multi-layer pigments.

9. The layer, sheet or film according to claim 1, wherein the effect pigments are based on synthetic or natural mica, flake-form glass substrates, flake-form SiO₂ substrates or flake-form Al₂O₃ substrates.

10. The layer, sheet or film according to claim 9, wherein the flake-form substrate is coated with one or more layers of metal oxides and/or metal oxide hydrates of Ti, Sn, Si, Al, Zr, Fe, Cr and Zn.

11. The layer, sheet or film according to claim 1, wherein it comprises two or more different effect pigments.

12. The layer, sheet or film according to claim 1, wherein the amount of effect pigments in the layer is in the range of 0.01 to 15% by weight.

13. The layer, sheet or film according to claim 1, wherein the thickness of the layer containing the effect pigments and the light scattering additive is in the range of 5 to 1000 μm.

14. The layer, sheet or film according to claim 1, which is a polymer based, sol-gel based, polysilazane based, glass based or ceramic based layer.

15. The layer, sheet or film according to claim 1, which is a polymer film.

16. The layer, sheet or film according to claim 1, which is a polymer sheet/film selected from polyolefins, polyethylene or a copolymer thereof.

17. The layer, sheet or film according to claim 1, which is a polymer sheet/film selected from EVA, EBA, EMA, EEA, POE, PC and BPO films, or PVB or TPU sheet/films.

18. The layer, sheet or film according to claim 1, which is a glass, ceramic or enamel layer.

19. A process of preparing a layer, sheet or film according to claim 1 by melt extrusion of a polymer material wherein the one or more effect pigments and one or more scattering additives are added to the polymer melt before extrusion.

20. A process of preparing a layer, sheet or film according to claim 19 by mixing the one or more effect pigments and one or more scattering additives with glass frits or a ceramic or enamel precursor, coating, printing or spraying the mixture onto a substrate and firing the mixture at a temperature above the glass temperature of the glass frits, ceramic or enamel, respectively.

21. The layer, sheet or film according to claim 1, which is an encapsulant film or sheet of a solar cell module.

22. A colored solar cell or colored solar cell module comprising a layer, sheet or film according to claim 1.

23. A colored solar cell or colored solar cell module comprising the following components:
a transparent front cover layer,
optionally a further transparent layer at the front side of the solar cell,
one or more solar cells, or an array of solar cells which are electrically interconnected by conducting parts, preferably by bus bars,
a rear sheet,
wherein the transparent front cover layer, or the further transparent layer at the front side of the solar cell, is a layer, sheet or film according to claim 1.

24. The colored solar cell or colored solar cell module according to claim 23, wherein the rear sheet is black or has dark color and/or the colored solar cell or colored solar cell module comprises an additional sheet or an encapsulant film provided between the solar cell(s) or solar cell array and the rear sheet, wherein said additional sheet or encapsulant film is black or has dark color.

25. The colored solar cell or colored solar cell module according to claim 21, wherein the conducting parts interconnecting the solar cells are colored black or in a dark color prior to the application of the layer with the effect pigments and the light scattering additive.

26. The colored solar cell or colored solar cell module according to claim 23, wherein a grid of dark color is incorporated into the solar cell(s) or solar cell array, said grid covering bright areas including but not limited to the space between the solar cells and the conducting parts.

27. The colored solar cell or colored solar cell module according to claim 23, wherein the front sheet and/or the back sheet is a glass sheet.

28. The colored solar cell or colored solar cell module according to claim 23, wherein the front sheet and/or the back sheet is a polymer sheet.

29. The colored solar cell or colored solar cell module according to claim 23, wherein it is selected from amorphous, mono- and multi crystalline silicon solar cells, CIGS-, CdTe-, III/V- or II/VI-solar cells, perovskite solar cells, quantum dot solar cells, organic solar cells and dye sensitized solar cells.

30. A process for preparing a colored solar cell or colored solar cell module according to claim 23, by stacking the components or layers in the desired sequence and then laminating the components or layers together by applying heat and/or pressure, or using an adhesive or a binding agent.

31. The process according to claim 30, wherein the layer, sheet or film containing the effect pigments and the light scattering additive is laminated to the front sheet in a first lamination step, and the front sheet with the laminated layer, sheet or film containing the effect pigments and the light scattering additive is laminated to the stack of the remaining components in a second lamination step.

32. The process according to claim 30, wherein the lamination steps are carried out by applying heat and/or pressure, or using an adhesive or a binding agent or layer, preferably in a vacuum press.

33. The colored solar cell or colored solar cell module according to claim 22, wherein the conducting parts interconnecting the solar cells are colored black or in a dark color prior to the application of the layer with the effect pigments and the light scattering additive.
